(19) United States
(12) Patent Application Publication
(10) Pub. No.: US 2025/0126880 A1
(43) Pub. Date: Apr. 17, 2025

(54) INTEGRATED CIRCUIT AND POWER CONVERTER

(71) Applicant: Nanjing Silergy Micro Technology Co., Ltd., Nanjing (CN)

(72) Inventors: Junyan Sun, Nanjing (CN); Wang Zhang, Nanjing (CN); Chen Zhao, Nanjing (CN)

(21) Appl. No.: 18/915,594

(22) Filed: Oct. 15, 2024

(30) Foreign Application Priority Data
Oct. 16, 2023 (CN) 202311339570.9

(51) Int. Cl. H01L 27/07; H01L 27/06; H01L 29/20; H02H 7/12; H02M 3/158

(52) U.S. Cl. CPC H10D 84/401; H10D 62/8503; H10D 84/01; H02H 7/1213; H02M 3/158

(57) ABSTRACT

An integrated circuit can include: a bottom structure; at least one GaN transistor die, where each GaN transistor die includes at least one power switching device; a silicon die including a control circuit for controlling the power switching device; and where the GaN transistor die and the silicon die are arranged on the bottom structure, and an electrical connection between the control circuit and the power switching device includes corresponding patterned metal structures arranged in the bottom structure.

### RELATED APPLICATIONS

This application claims the benefit of Chinese Patent Application No. 202311339570.9, filed on Oct. 16, 2023, which is incorporated herein by reference in its entirety.

### FIELD OF THE INVENTION

The present invention generally relates to the field of power electronics, and more particularly to integrated circuits and power converters.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads.

### BRIEF DESCRIPTION OF THE DRAWINGS

FIG. 1 is an equivalent circuit diagram of a power converter with parasitic inductances.

FIG. 2 is a circuit block diagram of a first example integrated circuit, in accordance with embodiments of the present invention.

FIG. 3 is a schematic circuit diagram of a first example integrated circuit, in accordance with embodiments of the present invention.

FIG. 4 is a schematic diagram of a first example integrated circuit, in accordance with embodiments of the present invention.

FIG. 5 is a schematic sectional view of a first example integrated circuit, in accordance with embodiments of the present invention.

FIG. 6 is a circuit block diagram of a second example integrated circuit, in accordance with embodiments of the present invention.

FIG. 7 is a schematic diagram of a second example integrated circuit, in accordance with embodiments of the present invention.

FIG. 8 is a schematic sectional view of a second example integrated circuit, in accordance with embodiments of the present invention.

FIG. 9 is a circuit block diagram of a third example integrated circuit, in accordance with embodiments of the present invention.

FIG. 10 is a schematic diagram of a third example integrated circuit, in accordance with embodiments of the present invention.

FIG. 11 is a schematic sectional view of a third example integrated circuit, in accordance with embodiments of the present invention.

FIG. 12 is a schematic circuit diagram of a first example power converter, in accordance with embodiments of the present invention.

FIG. 13 is a circuit block diagram of a fourth example integrated circuit, in accordance with embodiments of the present invention.

FIG. 14 is a schematic circuit diagram of a fourth example integrated circuit, in accordance with embodiments of the present invention.

FIG. 15 is a schematic diagram of a fourth example integrated circuit, in accordance with embodiments of the present invention.

FIG. 16 is a schematic sectional view of a fourth example integrated circuit, in accordance with embodiments of the present invention.

FIG. 17 is a schematic circuit diagram of a second example power converter, in accordance with embodiments of the present invention.

FIG. 18 is a circuit block diagram of a fifth example integrated circuit, in accordance with embodiments of the present invention.

FIG. 19 is a schematic circuit diagram of a fifth example integrated circuit, in accordance with embodiments of the present invention.

FIG. 20 is a schematic diagram of a fifth example integrated circuit, in accordance with embodiments of the present invention.

FIG. 21 is a schematic sectional view of a fifth example integrated circuit, in accordance with embodiments of the present invention.

FIG. 22 is a schematic circuit diagram of a third example power converter, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

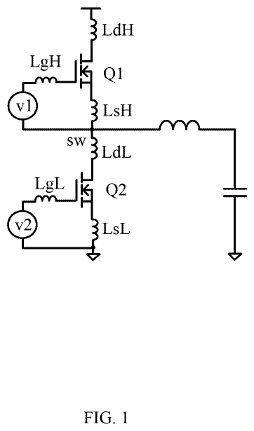

In order to realize high-frequency and high-efficiency DC-DC converter, it is very important to effectively reduce the adverse effects of parasitic inductors in the loop on circuit performance. Take Buck converter as an example, as shown in FIG. 1, there are some parasitic inductances (e.g., parasitic inductors LdH, LsH, LgH, LdL, LgL, LsL) at the source and drain of the power switching device in buck converter. These parasitic inductances may cause switching node SW to ring during the switching process, which will reduce the system efficiency and increase EMI. Especially, parasitic inductors LsH and LsL at the source may increase the current change conversion time during the on-state of the power switching device, which will greatly increase the switching loss of the system. Under some harsh conditions, resonance may occur among gate drive circuits V1 and V2, gate capacitor and parasitic inductor LsH, which makes the ringing amplitude of the power switching device higher than its turn-on voltage during hard switching, resulting in the short-circuited of the half-bridge arm, and seriously affecting the normal operation of the circuit.

Gallium nitride (GaN) transistors have high electron mobility. Compared with silicon transistors with the same on-chip resistance and the same breakdown voltage, GaN transistors can be made smaller and more compact. In addition, GaN transistors also have extremely fast switching speed and excellent reverse recovery performance, which is very important for realizing low loss and high efficiency applications. However, the ultra-high-speed switching of GaN transistors also brings new challenges, such as excessive ringing may lead to serious problems such as short-circuited of half-bridge arm. This puts forward higher requirements for the parasitic parameters of the driving circuit and the power circuit of GaN transistors.

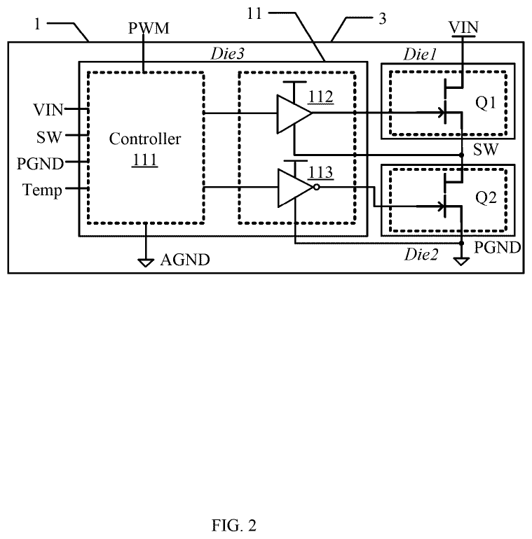

Referring now to FIG. 2, shown is a circuit block diagram of a first example integrated circuit, in accordance with embodiments of the present invention. In this particular example, integrated circuit 1 can include control circuit 11 and power switching devices Q1 and Q2. Control circuit 11 may include controller 111 and driving circuits 112 and 113 that can connect to power switching devices Q1 and Q2, respectively. Power switching devices Q1 and Q2 can connect in series; that is, one terminal of power switching device Q1 and one terminal of power switching device Q2 can connect to each other, the other terminal of power switching device Q1 can connect to input voltage pin VIN of integrated circuit 1, and the other terminal of power switching device Q2 can connect to power stage ground terminal PGND of integrated circuit 1. Control circuit 11 may have a plurality of input terminals and a plurality of output terminals including a control signal output terminal connected to the control terminals of power switching devices Q1 and Q2. Inside control circuit 11, the control signal output terminal of controller 111 can connect to the input terminals of driving circuits 112 and 113, respectively.

Also, the output terminals of driving circuits 112 and 113 can connect to the control terminals of power switching devices Q1 and Q2, respectively. In addition, the power supply terminals of driving circuits 112 and 113 can connect to the pull-up voltage pin of the integrated circuit or the internal pull-up voltage terminal. In this example, driving circuits 112 and 113 may be buffers. Controller 111 can also include one or more of input voltage pin VIN, power stage ground terminal PGND, control stage ground terminal AGND, pulse width modulation signal input/output terminal PWM, temperature detection output terminal Temp, and so on. It should be understood that the input terminals or output terminals of controller 111 in FIG. 2 are certain examples, and those skilled in the art will recognize that more or less inputs or outputs of controller 111 can be utilized according to the particular application.

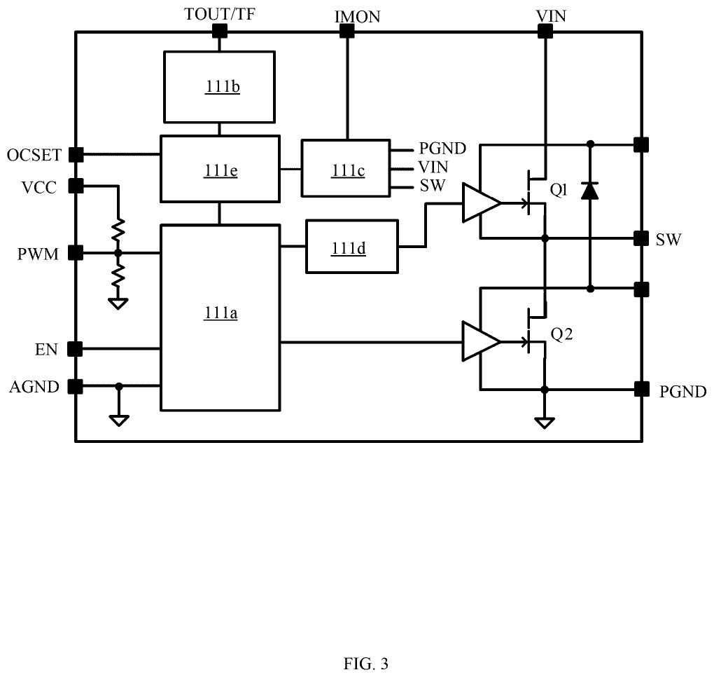

Referring now to FIG. 3, shown is a schematic circuit diagram of a first example integrated circuit, in accordance with embodiments of the present invention. In this particular example, controller 111 can include a plurality of circuit modules, such as control logic unit 111a, temperature detection and error indication unit 111b, current detection unit 111c, level adjustment unit 111d, and protection unit 111e. For example, control logic unit 111a can output corresponding control signals according to various detection signals (e.g., temperature, input voltage, output voltage, inductor current, output current or input current, etc.) input by other units. Control logic unit 111a can connect to power supply pin VCC, pulse width modulation signal input/output pin PWM, enable signal pin EN, and control stage ground pin AGND. Temperature detection and error indication unit 111b can connect to pin TOUT/FT for providing a temperature detection result or an error indication.

Pin TOUT/FT may output temperature sampling signal under a normal operating condition, and may be pulled to the high level, in order to inform the external controller that the integrated circuit has failed under a fault operating condition. Current detection unit 111c can connect to pin IMON, input voltage pin VIN, common terminal pin SW, and power stage ground terminal PGND. Current detection unit 111c can sample the current flowing through power switching devices Q1 and Q2, and may provide the current sampling signal through pin IMON for the external controller. Level adjustment unit 111d can connect between control logic unit 111a and the driving circuit for driving power switching device Q1, and for adjusting the level output to the driving circuit. Protection unit 111e can connect to protection setting pin OCSET, and protection unit 111e can connect to control logic unit 111a, temperature detection and error indication unit 111b, and current detection unit 111c for providing the peak current protection for high-terminal power devices, the negative current protection for low-terminal power devices, the half-bridge through protection, the over-temperature protection, the under-voltage/overvoltage protection of the system voltage, and so on. For example, the peak current protection threshold can be set through protection setting pin OCSET.

In this particular example, as shown in FIG. 2, control circuit 11 and power switching devices Q1 and Q2 may be integrated in the same integrated circuit. Power switching device Q1 can be arranged on GaN transistor die Die1, and power switching device Q2 may be arranged on GaN transistor die Die2, which can be independent from GaN transistor die Die1. Control circuit 11 may be arranged on silicon die Die3. GaN transistor dies/dice Diel and Die2 and silicon die Die3 can be arranged on the same bottom structure, such that control circuit 11 and power switching devices Q1 and Q2 can connect with each other based on the bottom structure. By being integrated in the same integrated circuit package, a more integrated circuit structure that can build a power converter can be formed. Here, the GaN transistor die may refer to a die prepared with GaN as the main substrate material. As discussed above, the power switching device based on GaN substrate may have extremely fast switching speed and excellent reverse recovery performance.

In particular embodiments, the die may refer to a single small chip cut from a wafer after the wafer is manufactured, but that is not packaged and wired. In this example, the bottom structure can be configured as a printed-circuit board (PCB) for chip packaging, or a redistribution layer (RDL) used in the FANOUT process. For example, the printed circuit board can be based on an insulated substrate, such as FR-4 and CEM-3, and can be formed by patterning metal foil wiring on the surface of the insulated substrate, or formed by patterning metal foil wiring inside the insulated substrate in a multiple layer form. In this example, GaN transistor dies Die1, Die2, and silicon die Die3 can connect by conductors in the bottom structure according to particular connection example shown in FIG. 2. Because of the relatively short distance between the connecting terminals in the bottom structure and the high integration, the negative influence of parasitic effect can be effectively reduced, the size of the power converter based on the integrated circuit reduced, the switching frequency improved, and the system efficiency increased.

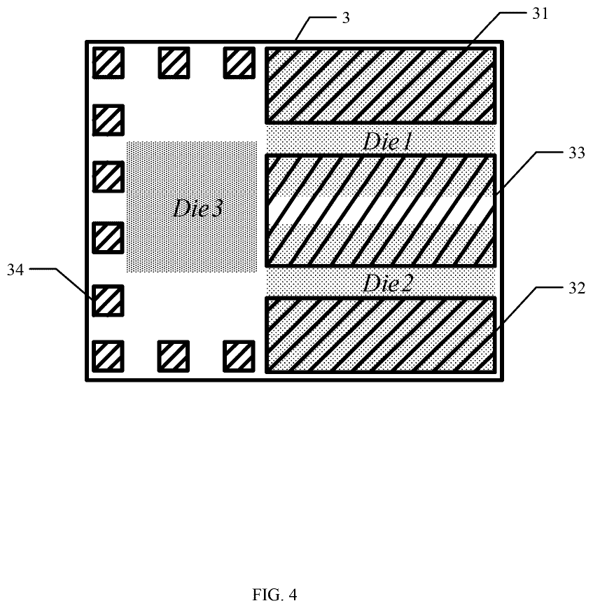

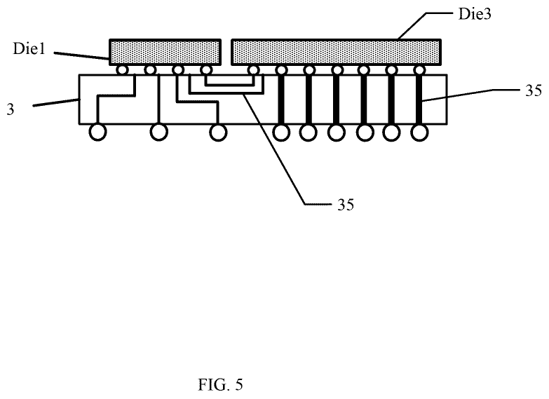

Referring now to FIG. 4, shown is a schematic diagram of a first example integrated circuit, in accordance with embodiments of the present invention. Referring also to FIG. 5, shown is a schematic sectional view of a first example integrated circuit, in accordance with embodiments of the present invention. FIG. 4 shows an example arrangement of the integrated circuit from the bottom perspective, and FIG. 5 shows the dies connected by the bottom structure from the side perspective. As shown in FIGS. 4 and 5, GaN transistor dies Die1 and Die2 can be arranged side by side on the first surface of bottom structure 3, and silicon die Die3 may also be arranged on the first surface of bottom structure 3. The second surface of bottom structure 3 (that is, the opposite surface of the first surface) can be provided with first pin 31 connected to the first terminal of power switching device Q1, third pin 33 connected to the second terminal of power switching device Q2, and second pin 32 connected to common node SW between power switching devices Q1 and Q2. In this example, the first surface is the top surface of the bottom structure, and the second surface is the bottom surface of the bottom structure.

As shown in FIG. 4, GaN transistor dies Die1 and Die2 can be arranged side by side along a first direction, and the first surface of bottom structure 3 may include a first side and a second side along a second direction, where the first direction and the second direction are perpendicular. GaN transistor dies Die1 and Die2 can be arranged side by side are located on the first side of the first surface of bottom structure 3, and silicon die Die3 arranged on the second side of the first surface of bottom structure 3. For example, GaN transistor dies Die1 and Die2 and silicon die Die3 can connect to the first surface of bottom structure 3 by welding. Since silicon die Die3 here is provided with more connection terminals, a plurality of fourth pins 34 electrically connected to the control circuit in silicon die Die3 may be provided around silicon die Die3. Because the fourth pin can connect to the control circuit, the current difference between the control stage and the power stage may be relatively large, so the areas of first to third pins 31-33 connected to the power switching device can be larger than the areas of each fourth pin 34.

In addition, first pin 31, third pin 33, and second pin 32 can be arranged along the arrangement direction of GaN transistor dies Diel and Die2, which can be sequentially arranged from top to bottom in FIG. 4. The projection of third pin 33 can cover the adjacent area of GaN transistor dies Die1 and Die2. Further, first to third pins 31-33 may all be formed in a rectangular shape, and the width of each of first to third pins 31-33 may essentially be the same as that of the GaN transistor die. It should be understood that the sizes and shapes of the first to fourth pins can also be set according to the specific needs of integrated circuit design. As shown in FIG. 5, silicon die Die3 and GaN transistor dies Die1 and Die2 can connect to the pins on the second surface of bottom structure 3 through metal structures 35 and vias that are formed in bottom structure 3, and may also be connected to each other through internal metal structures 35 and vias.

In this example, the GaN transistor die with power switching devices and the silicon die with control circuit can be integrated on the same bottom structure, in order to form a driving integrated circuit with control functionality. Because the length of wires inside the integrated circuit is relatively short and the contact surface of wires inside the integrated circuit relatively large, the parasitic effect between different power switching devices of the die can effectively be reduced, and the chip performance accordingly improved.

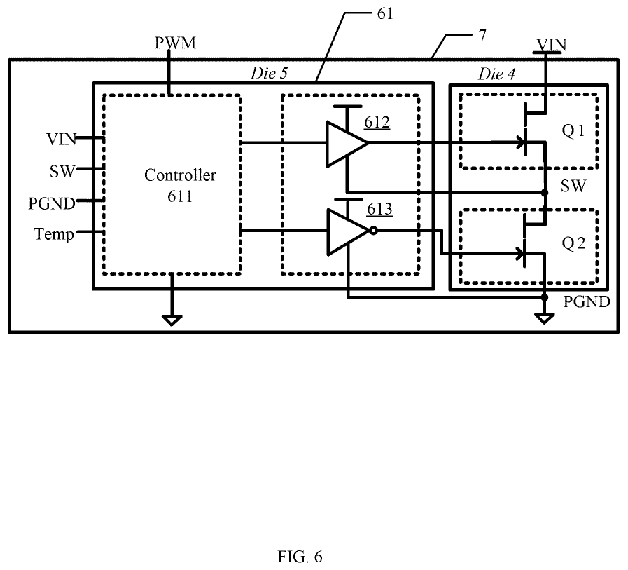

Referring now to FIG. 6, shown is a circuit block diagram of a second example integrated circuit, in accordance with embodiments of the present invention. In this particular example, power switching devices Q1 and Q2 can be arranged on the same GaN transistor die Die4. That is, two power switching devices Q1 and Q2 may be formed on GaN transistor die Die4, and power switching devices Q1 and Q2 can be electrically connected through metal interconnection lines or through holes/vias inside the GaN transistor die. Control circuit 61 may be disposed on silicon die Die5. In addition, silicon die Die5 and GaN transistor die Die4 may be arranged on the same bottom structure 7, and power switching devices Q1 and Q2 can connect with control circuit 61 through the metal structure in bottom structure 7.

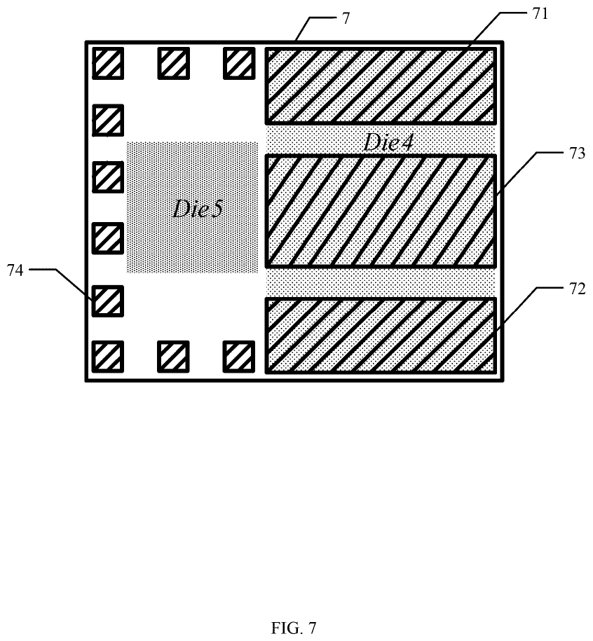

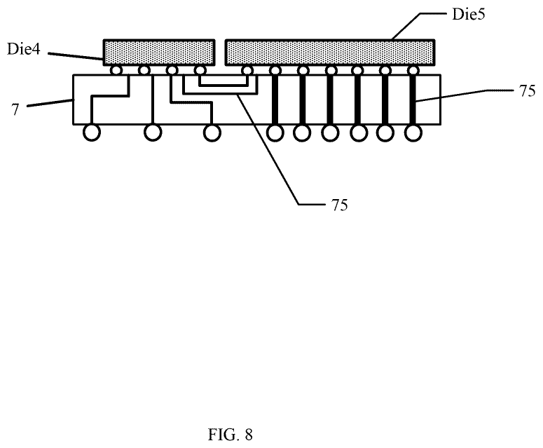

Referring now to FIG. 7, shown is a schematic diagram of a second example integrated circuit, in accordance with embodiments of the present invention. Referring also to FIG. 8, shown is a schematic sectional view of a second example integrated circuit, in accordance with embodiments of the present invention. In FIGS. 7 and 8, GaN transistor die Die4 and silicon die Die5 may be disposed on the first surface of bottom structure 7. First pin 71, second pin 72, and third pin 73 can connect to GaN transistor die Die4. Also, a plurality of fourth pins 74 connected to silicon die Die5 may be provided on the second surface of bottom structure 7 (e.g., the opposite surface of the first surface). First pin 71 can connect to a first terminal of power switching device Q1, which is a terminal that may not be connected to power switching device Q2. Third pin 73 can connect to a second terminal of power switching device Q2, which is the terminal may not be connected to power switching device Q1. Common node SW between power switching devices Q1 and Q2 can connect to second pin 72.

The silicon die Die5 may be disposed in an unoccupied area on the other side of the first surface. Fourth pins 74 can be disposed around silicon die Die5. For example, the areas of the first to third pins can be much larger than the areas of the fourth pins. First pin 71, third pin 73, and second pin 72 can be arranged along the arrangement direction of the power switching devices in GaN transistor die Die4, and sequentially arranged from top to bottom in FIG. 7. For example, first to third pins 71 to 73 can each be formed in a rectangular shape. As shown in FIG. 8, silicon die Die5 and GaN transistor die Die4 can connect to the pins on the second surface of bottom structure 7 through metal structures 75 and vias formed in bottom structure 7, and can also connect to each other through metal structures 75 and vias.

In this particular example, a plurality of power switching devices can be integrated in the same GaN transistor die, thereby improving the integration degree of the power switching devices, reducing the parasitic effect of the power switching devices, reducing the size of the power converter built based on the integrated circuit, improving the switching frequency, and increasing the system efficiency.

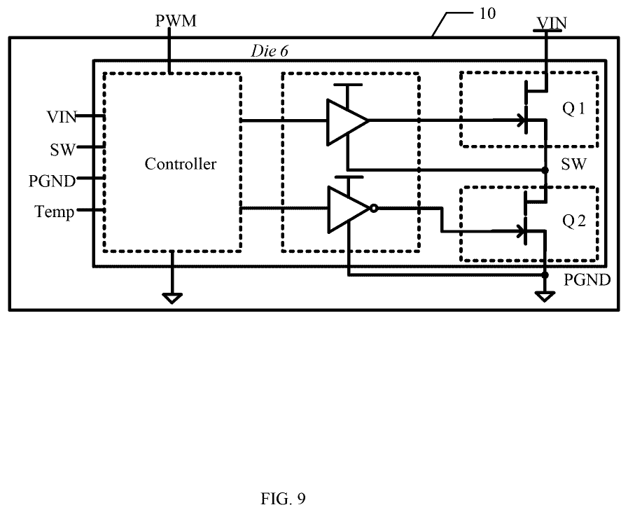

Referring now to FIG. 9, shown is a circuit block diagram of a third example integrated circuit, in accordance with embodiments of the present invention. In this particular example, power switching device Q1, power switching device Q2, and control circuit 91 can be arranged on the same GaN transistor die Die6. That is, two power switching devices Q1 and Q2 may be formed on GaN transistor die Die6, and power switching devices Q1 and Q2 can be electrically connected through metal interconnection lines or through holes/vias inside the GaN transistor die. Control circuit can also be arranged on GaN transistor die Die6. GaN transistor die Die6 may be packaged into an integrated circuit package through bottom structure 10, and external connection terminals of power switching devices Q1 and Q2 and control circuit can be led out through the metal structure in bottom structure 10.

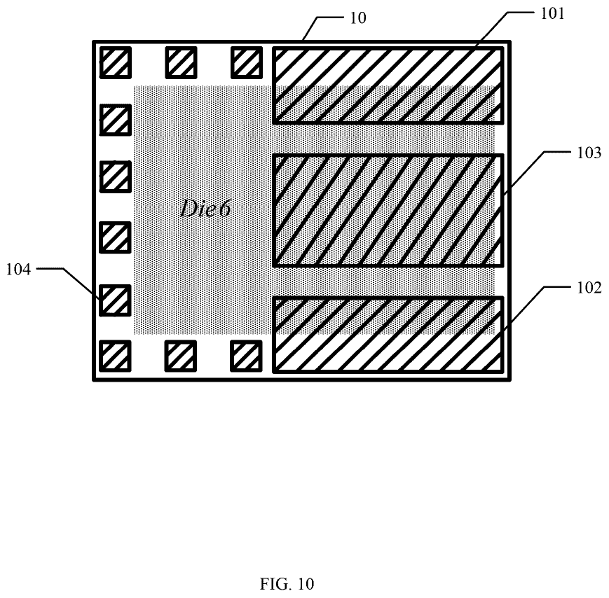

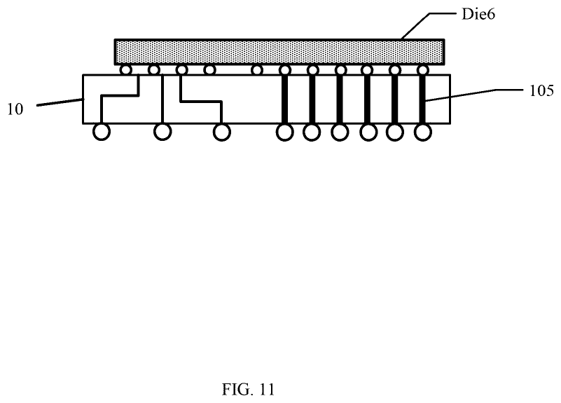

Referring now to FIG. 10, shown is a schematic diagram of a third example integrated circuit, in accordance with embodiments of the present invention. Referring also to FIG. 11, shown is a schematic sectional view of a third example integrated circuit, in accordance with embodiments of the present invention. As shown in FIGS. 10 and 11, GaN transistor die Die6 may be disposed on the first surface of bottom structure 10. First pin 101, second pin 102, and third pin 103 can connect to power switching devices Q1 and Q2 in GaN transistor die Die6, and a plurality of fourth pins 104 connected to the control circuit in GaN transistor die Die6 can be provided on the second surface (that is, the opposite surface to the first surface) of bottom structure 10. First pin 101 can connect to the first terminal of power switching device Q1, which may not be connected to power switching device Q2. Third pin 103 can connect to the second terminal of power switching device Q2, which may not be connected to power switching device Q1.

Common node SW between power switching devices Q1 and Q2 can connect to second pin 102. Fourth pin 104 may be arranged around a part of the edge of the control circuit in GaN transistor die Die6. For example, the areas of the first to third pins can be larger than the areas of the fourth pins. First pin 101, third pin 103, and second pin 102 can be arranged along the arrangement direction of the power switching devices in GaN transistor die Die6, and sequentially arranged from top to bottom in FIG. 10. For example, first to third pins 101-103 can each be formed in a rectangular shape. As shown in FIG. 11, GaN transistor die Die6 can connect to each pin on the second surface of bottom structure 10 through metal structures 105 and vias formed in bottom structure 10.

In this example, a plurality of power switching devices and a control circuit can be integrated in the same GaN transistor die, thereby improving the integration degree of the power switching devices, reducing the parasitic effect of the power switching devices, reducing the size of a power converter built based on the integrated circuit, improving the switching frequency, and increasing the system efficiency.

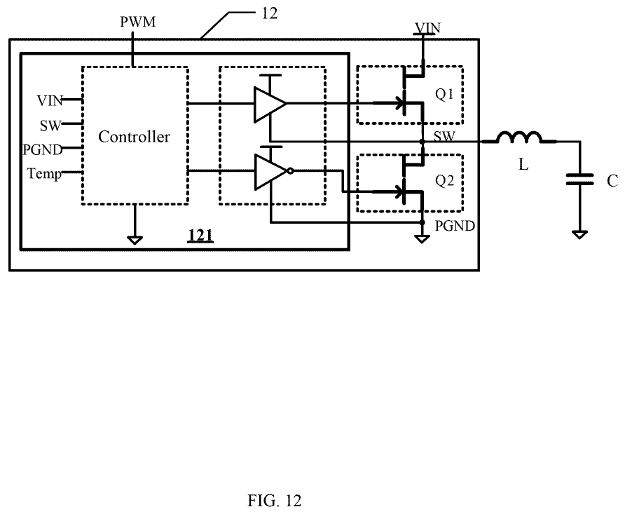

Referring now to FIG. 12, shown is a schematic circuit diagram of a first example power converter, in accordance with embodiments of the present invention. In this particular example, power switching devices Q1 and Q2 and control circuit 121 can be integrated in integrated circuit 12 in different ways. The common node between power switching devices Q1 and Q2 may be led out through pin SW. Outside integrated circuit 12, one terminal of inductor L can connect to pin SW, and capacitor C can connect to the other terminal of inductor L, in order to form a buck power converter topology. It should be understood that by changing the connection relationship of the power switching devices in integrated circuit 12, the integrated circuit can also be made suitable for building a power converter of other topologies (e.g., boost power converter, etc.).

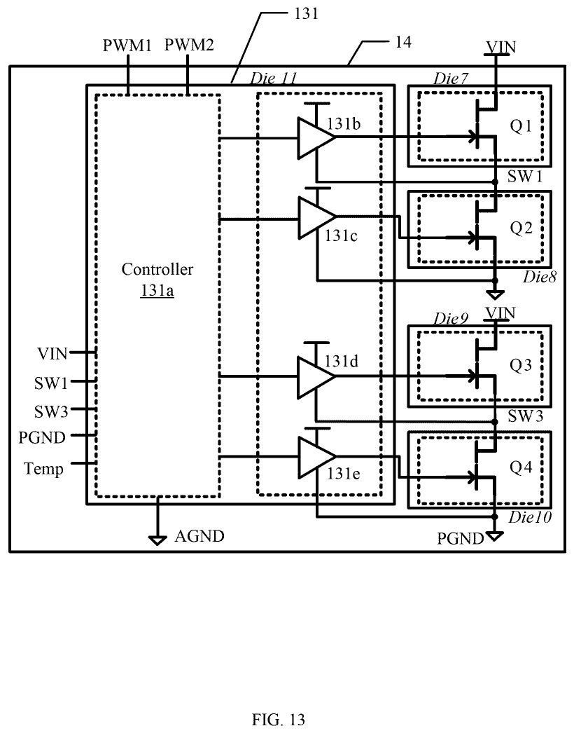

Referring now to FIG. 13, shown is a circuit block diagram of a fourth example integrated circuit, in accordance with embodiments of the present invention. In this particular example, integrated circuit 13 can include control circuit 131 and power switching devices Q1, Q2, Q3, and Q4. Control circuit 131 may include controller 131a and driving circuits 131b-131e respectively connected to power switching devices Q1-Q4. Power switching devices Q1 and Q2 can connect in series to form a first branch. Power switching devices Q3 and Q4 can connect in series to form a second branch. The first and second branches can connect in parallel between input voltage pin VIN and power stage ground terminal PGND. For example, one terminal of power switching device Q1 can connect to input voltage pin VIN, and the other terminal of power switching device Q1 can connect to power switching device Q2. One terminal of power switching device Q2 can connect to power switching device Q1, and the other terminal of power switching device Q2 can connect to power stage ground terminal PGND. One terminal of power switching device Q3 can connect to input voltage pin VIN, and the other terminal of power switching device Q3 can connect to power switching device Q4. One terminal of power switching device Q4 can connect to power switching device Q3, and the other terminal of power switching device Q4 can connect to power stage ground terminal PGND. Control circuit 131 may have a plurality of input terminals and a plurality of output terminals including control signal output terminals, respectively connected to the control terminals of power switching devices Q1-Q4.

Within control circuit 131, the output terminals of controller 131a can connect to the input terminals of driving circuits 131b-131e, respectively. Output terminals of driving circuits 131b-131e can respectively be connected to control signal output terminals of control circuit 131. In addition, the power supply terminals of driving circuits 131b-131e can connect to the pull-up voltage pin or the internal pull-up voltage terminal of the integrated circuit. In this example, driving circuits 131b-131e may be buffers. Controller 131 also can include another input terminal or output terminal (e.g., input voltage pin VIN, control stage ground terminal AGND, pulse width modulation signal input terminals PWM1, PWM2, etc.). It should be understood that the above-mentioned input terminals and output terminals of controller 131 are examples, and those skilled in the art can flexibly set more or less input and output terminals of controller 131 according to certain applications.

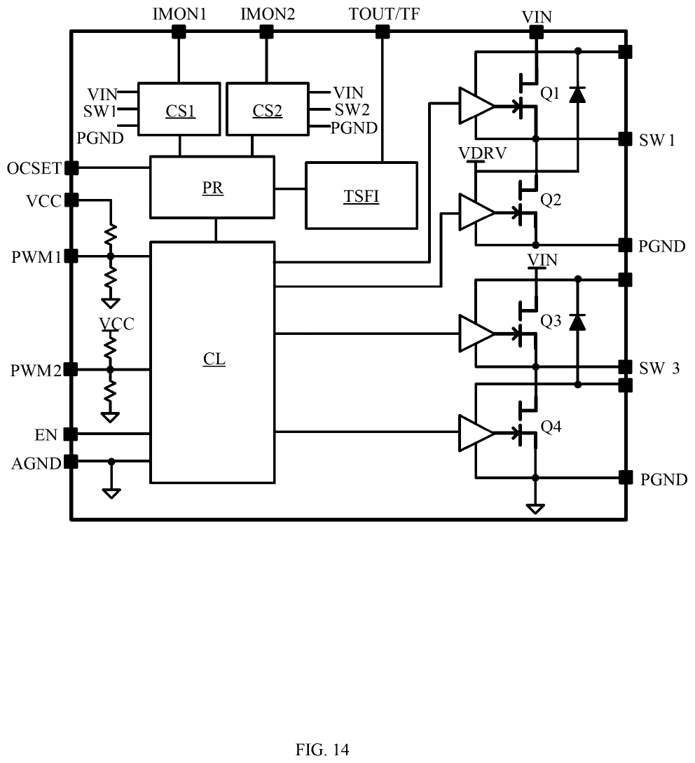

Referring now to FIG. 14, shown is a schematic circuit diagram of a fourth example integrated circuit, in accordance with embodiments of the present invention. In this particular example, controller 131a may include a plurality of circuit modules, including control logic unit CL, temperature detection and error indication unit TSFI, current detection units CS1 and CS2, and protection unit PR. Control logic unit CL can output corresponding control signals according to the detection signal (e.g., one or more of the temperature, the input voltage, the output voltage, the inductor current, the output current and the input current, etc.) input by other units. Control logic unit CL can connect to power supply pin VCC, PWM signal input/output pins PWM1 and PWM2, enable signal pin EN, and control stage ground pin AGND. Temperature detection and error indication unit TSFI can connect to pin TOUT/FT for outputting the temperature detection result or error indication. Pin TOUT/FT may output temperature sampling signal under normal operating conditions, and may be pulled to the high level under fault operating conditions to inform the external controller of the fault.

Current detection unit CS1 can connect to pin IMON1, current detection unit CS2 can connect to pin IMON2, and both current detection units CS1 and CS2 can connect to input voltage pin VIN, corresponding common node SW, and power stage ground terminal PGND. Current detection units CS1 and CS2 can respectively sample the current flowing through the first and second branches, and respectively output corresponding current sampling signals through pin IMON1 and pin IMON2 for the external controller. Protection unit PR can connect to protection setting pin OCSET, and to temperature detection and error indication unit TSFI and current detection units CS1 and CS2 (e.g., for providing peak current protection, negative current protection, half-bridge straight-through protection, over-temperature protection or under-voltage/overvoltage protection of system voltage, etc.). For example, the peak current protection threshold can be set through protection setting pin OCSET.

Referring back to FIG. 13, in one embodiment, control circuit 131 and power switching devices Q1-Q4 can be integrated in the same integrated circuit. In this example, power switching device Q1 can be arranged on GaN transistor die Die7, power switching device Q2 on GaN transistor die Die8, power switching device Q3 on GaN transistor die Die9, power switching device Q4 on GaN transistor die Die10, and control circuit 131 on silicon die Die11. GaN transistor dies Die7-Die10 can be four independent dies. GaN transistor dies Die7-Die10 and silicon die Die11 may be arranged on the same bottom structure, such that control circuit 131 and power switching devices Q1-Q4 can connect with each other based on the bottom structure, in order to form a power converter. In this example, GaN transistor dies Die7-Die10 and silicon die Die11 can connect by conductors in the bottom structure according to the connection example of FIG. 13. Because of the relatively short distance between the connecting terminals in the bottom structure and high integration of the connecting terminals, the negative influence of parasitic effect can be effectively reduced, the size of the power converter based on the integrated circuit reduced, the switching frequency improved, and the system efficiency increased.

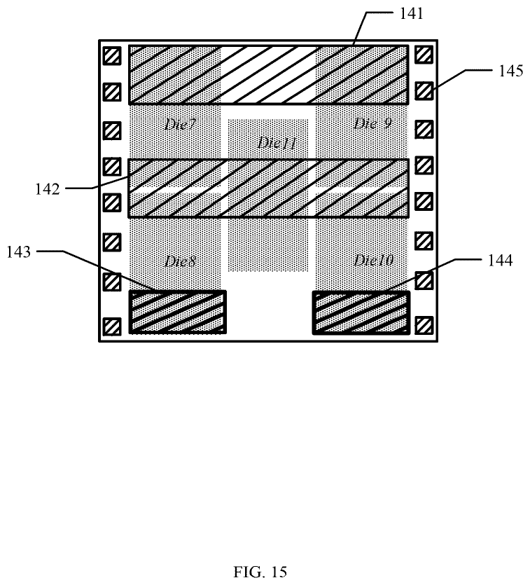

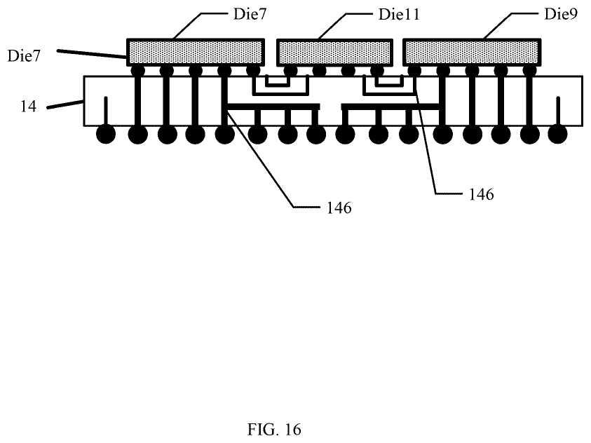

Referring now to FIG. 15, shown is a schematic diagram of a fourth example integrated circuit, in accordance with embodiments of the present invention. Referring now to FIG. 16, shown is a schematic sectional view of a fourth example integrated circuit, in accordance with embodiments of the present invention. FIG. 15 shows the arrangement of integrated circuits in this embodiment from the bottom perspective, and FIG. 16 shows the dies connected by the bottom structure from the side perspective. In FIGS. 15 and 16, GaN transistor dies Die7-Die10 and silicon die Die11 may be disposed on the first surface of bottom structure 14. The second surface of bottom structure 14 (that is, the opposite surface of the first surface) can be provided with first pin 141 connected to the first terminal of power switching device Q1 and first terminal of power switching device Q3, second pin 142 connected to the second terminal of power switching device Q2 and the second terminal of power switching device Q4, third pin 143 connected to the common node between power switching devices Q1 and Q2, and fourth pin 144 connected to the common node between power switching device Q3 and power switching device Q4.

Silicon die Die11 may be disposed in the middle of the first surface. GaN transistor dies Die7 and Die8 can be arranged on one side of silicon die Die11, and GaN transistor dies Die9 and Die10 arranged on the other side of silicon die Die11. In this example, first pin 141 can be formed in a rectangular shape, and its long edge may extend in the arrangement direction of GaN transistor die Die7 where power switching device Q1 is located and GaN transistor die Die9 where power switching device Q3 is located. This can allow first pin 141 to be partially located below GaN transistor die Die7 and partially located below GaN transistor die Die9, such that first pin 141 can connect to the corresponding GaN transistor die in the shortest distance through the through hole in the bottom structure, thus further optimizing the parasitic effect.

That is, the projection of first pin 141 can cover the upper regions of GaN transistor die Die7 and GaN transistor die Die9. Similarly, second pin 142 can be formed into a rectangular shape, and arranged in the middle of the first surface, and its long edge can extend in the arrangement direction of GaN transistor die Die8 where power switching device Q2 is located and GaN transistor die Die10 where power switching device Q4 is located. This can cause the projection of second pin 142 to cover the adjacent areas of GaN transistor dies Die7 and Die8, the adjacent areas of GaN transistor dies Die9 and Die10, and a part of silicon die Die11. Third pin 143 and fourth pin 144 can be disposed in the lower region of the first surface. The projection of third pin 143 can cover the lower region of GaN transistor die Die8. The projection of fourth pin 144 can cover the lower region of GaN transistor die Die10. The above arrangement can make the overlapping area between second pin 142 as the ground terminal and each of third pin 143 and fourth pin 144 smaller, which may reduce the output junction capacitance.

Due to this arrangement, the lead-out terminal of each die may be connected to the corresponding pin through the conductive structure inside the bottom structure. In this example, silicon die Die11 can connect to the outside device of the integrated circuit through a plurality of fifth pins 145. Fifth pin 145 can be disposed at the edge of the second surface of the bottom structure. Because fifth pin 145 can connect to the control circuit, the current difference between the control stage and the power stage may be relatively large, so the areas of first to fourth pins 141-144 connected to the power switching device may be larger than the area of each of fifth pins 145. First pin 141 and second pin 142 can each be formed in a rectangular shape, and their lengths may span the second surface of bottom structure 14 (e.g., their lengths can extend from one side of GaN transistor dies Die7 away from silicon die Die11 to one side of GaN transistor die Die9 away from silicon die Die11), partially covering areas of the dies of the two GaN transistors located on left and right sides of the second surface. Third pin 143 and fourth pin 144 may also be formed in a rectangular shape, and their lengths can be equal to or greater than the width of the GaN transistor die, but the sizes and shapes of first to fifth pins 141-145 can also be set according requirements of the integrated circuit design. As shown in FIG. 16, silicon die Die11 and GaN transistor dies Die7-Die10 can connect to the pins on the second surface of bottom structure 14 through metal structures 146 and vias formed in bottom structure 14, and also can connect to each other through internal metal structure 146 and vias.

While FIG. 15 shows an exemplary arrangement way of GaN transistor die Die7-Die10, the particular arrangement of the GaN transistor dies and the silicon die on the bottom structure can be adjusted in certain embodiments. For example, the positions of GaN transistor dies Die7 and Die9 can be interchanged, and the positions of GaN transistor dies Die8 and Die10 can be interchanged. In another example, the GaN transistor dies can be arranged together in a matrix, the silicon die arranged at one side of the matrix formed by the GaN transistor dies, and the positions and sizes of pins adaptively adjusted.

In order to further improve the integration, the power switching devices in the same branch can also be integrated in one GaN transistor die. That is, two GaN transistor dies can be adopted, and each GaN transistor die provided with two interconnected power switching devices. Also, all the power switching devices can be integrated in the same GaN transistor die, or all the power switching devices and the control circuit can be integrated together in the same GaN transistor die.

In this example, the GaN transistor die with power switching devices and the silicon die with control circuit can be integrated on the same bottom structure, in order to form a driving integrated circuit with control functionality. Due to the relatively short length of wires inside the integrated circuit and the relatively large contact surface of wires inside the integrated circuit, the parasitic effect between different power switching devices of the GaN transistor die can be effectively reduced and the chip performance improved.

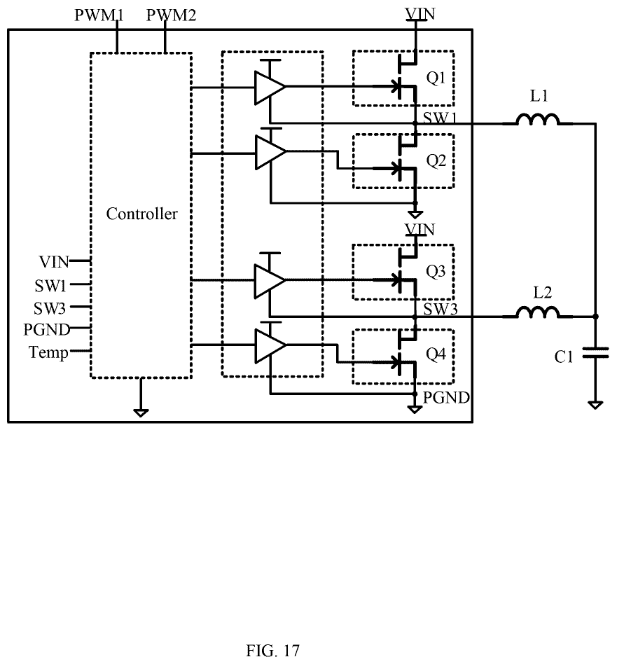

The integrated circuit of this example can be used to build a non-isolated two-phase buck power converter. Referring now to FIG. 17, shown is a schematic circuit diagram of a second example power converter, in accordance with embodiments of the present invention. In this particular example, the common node of the first branch formed by power switching devices Q1 and Q2 can be led out through pin SW1. The common node of the second branch formed by power switching devices Q3 and Q4 may be led out through pin SW3. Outside the integrated circuit, one terminal of inductor L1 can connect to pin SW1, the other terminal of inductor L1 can connect to capacitor C1, one terminal of inductor L2 can connect to pin SW3, and the other terminal of inductor L2 can connect to capacitor C1, thus forming a non-isolated two-phase buck power converter. By changing the connection relationship of power switching devices in the integrated circuit, the integrated circuit can also be made suitable for building other topological types of power converter (e.g., non-isolated two-phase boost power converters, etc.).

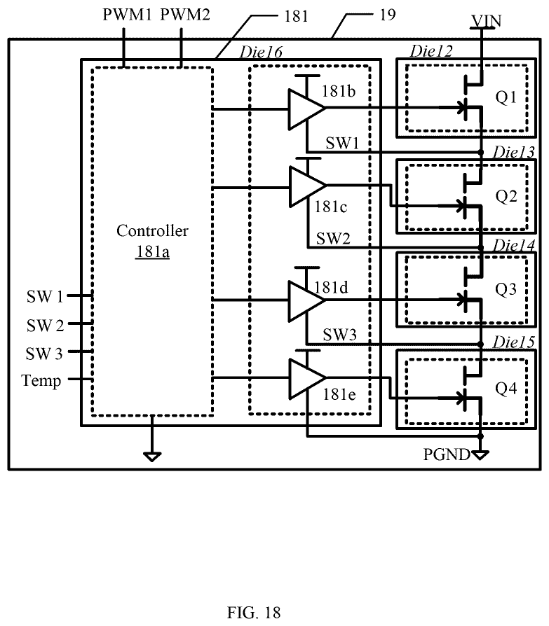

Referring now to FIG. 18, shown is a circuit block diagram of a fifth example integrated circuit, in accordance with embodiments of the present invention. In this particular example, integrated circuit 18 can include control circuit 181 and power switching devices Q1, Q2, Q3, and Q4. Control circuit 181 may include controller 181a and driving circuits 181b-181e respectively connected to power switching devices Q1-Q4. Power switching devices Q1-Q4 can connect in series between input voltage pin VIN and power stage ground terminal PGND. That is, one terminal of power switching device Q1 can connect to input voltage pin VIN, the other terminal of power switching device Q1 can connect to one terminal of power switching device Q2, the other terminal of power switching device Q2 can connect to one terminal of power switching device Q3, the other terminal of power switching device Q3 can connect to one terminal of power switching device Q4, and the other terminal of power switching device Q4 can connect to power stage ground terminal PGND. Control circuit 181 may have a plurality of input terminals and output terminals comprising control signal output terminals connected to the control terminals of power switching devices Q1-Q4.

Inside control circuit 181, the output terminals of controller 181a can connect to the input terminals of driving circuits 181b-181e, respectively, and the output terminals of driving circuits 181b-181e can connect to control signal output terminals of control circuit 181. In addition, the power supply terminals of driving circuits 181b-181e can connect to the pull-up voltage pin or the internal pull-up voltage terminal of the integrated circuit. In this example, driving circuits 181b-181e may be set as buffers. Controller 181 can also include, e.g., common terminals SW1, SW2, SW3, control stage ground terminal AGND, pulse width modulation signal input terminals PWM1, PWM2, as a few examples. It should be understood that the above-mentioned input terminals and output terminals of controller 181 are examples, and those skilled in the art will recognize that more or less input terminals and output terminals of controller 131 can be utilized in certain applications.

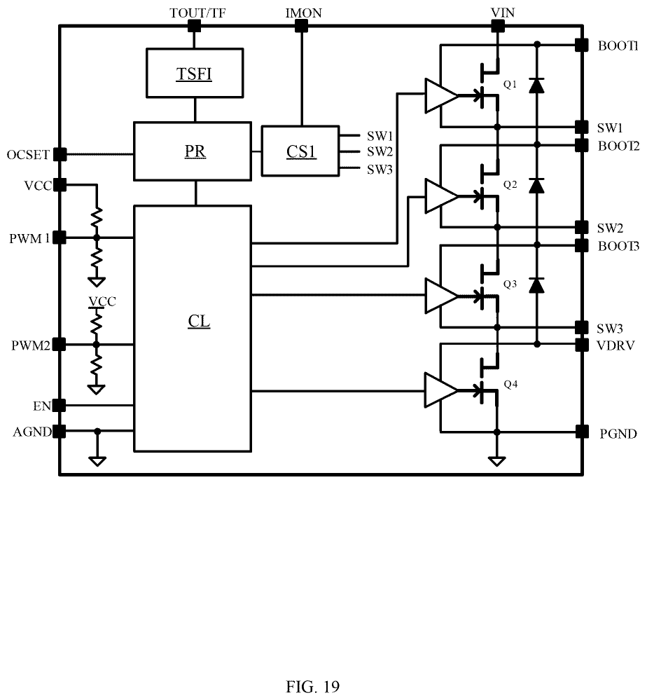

Referring now to FIG. 19, shown is a schematic circuit diagram of a fifth example integrated circuit, in accordance with embodiments of the present invention. In this particular example, controller 181a may include a plurality of circuit modules including control logic unit CL, temperature detection and error indication unit TSFI, current detection unit CS and protection unit PR. Control logic unit CL can output corresponding control signals in a set way according to the detection signal (e.g., the detection signal can be configured as one or more of temperature, input voltage, output voltage, inductor current, output current and input current, etc.) input by other units. Control logic unit CL can connect to power supply pin VCC, PWM signal input/output pins PWM1 and PWM2, enable signal pin EN, and control stage ground pin AGND. Temperature detection and error indication unit TSFI can connect to pin TOUT/FT used for outputting the temperature detection result or error indication.

Pin TOUT/FT can be output temperature sampling signal under a normal operating condition, and can be pulled to a high level under a fault operating condition, in order to inform the external controller of the fault. Current detection unit CS can connect to pin IMON and common terminals SW1-SW3. Current detection unit CS can sample the currents flowing through power switching devices Q1-Q4, respectively, and output current sampling signals through pin IMON for an external controller. Protection unit PR can connect to protection setting pin OCSET, and protection unit PR can connect to temperature detection and error indication unit TSFI and current detection unit CS for providing peak current protection, negative current protection, half-bridge straight-through protection, over-temperature protection, under-voltage/overvoltage of the system voltage, etc, where the peak current protection threshold can be set through protection setting pin OCSET.

Referring back to FIG. 18, control circuit 181 and power switching devices Q1-Q4 can be integrated in the same integrated circuit. In this example, power switching device Q1 can be arranged on GaN transistor die Die12, power switching device Q2 on GaN transistor die Die13, power switching device Q3 on GaN transistor die Die14, power switching device Q4 on GaN transistor die Die15, and control circuit 181 on silicon die Die16. GaN transistor dies Die12-Die15 can be four independent dies. GaN transistor dies Die12-Die15 and silicon die Die16 may be arranged on the same bottom structure, such that control circuit 181 and power switching devices Q1-Q4 can connect with each other based on the bottom structure, and may form a power converter. In this example, GaN transistor dies Die12-Die15 and silicon die Die16 can connect by the conductor in the bottom structure, e.g., as shown in FIG. 18. Because of the relatively short distance between the connecting terminals in the bottom structure and relatively high integration of the connecting terminals in the bottom structure, the negative influence of parasitic effect can be effectively reduced, the size of the power converter based on the integrated circuit can be reduced, the switching frequency can be improved, and the system efficiency can be increased.

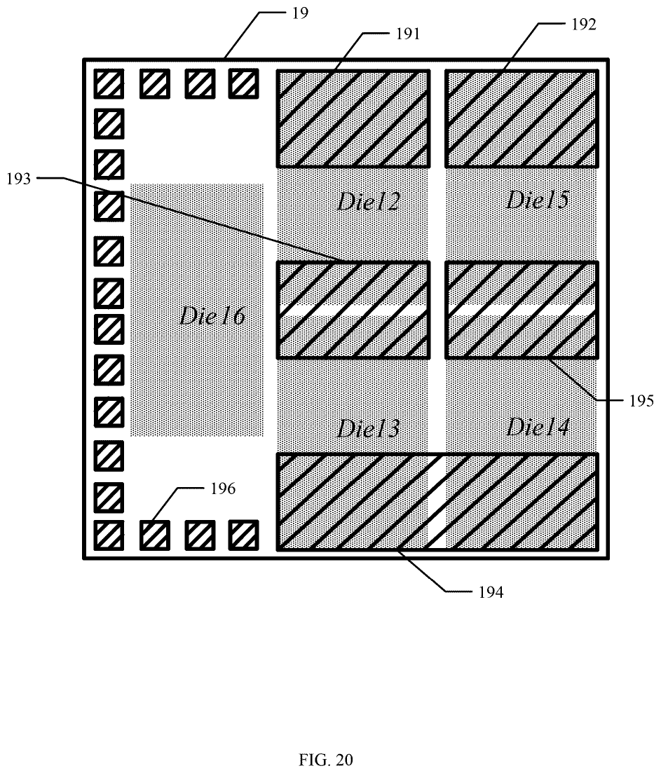

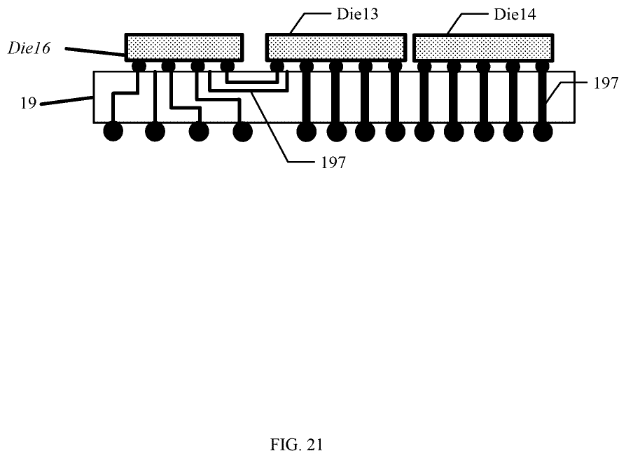

Referring now to FIG. 20, shown is a schematic diagram of a fifth example integrated circuit, in accordance with embodiments of the present invention. Referring also to FIG. 21, shown is a schematic sectional view of a fifth example integrated circuit, in accordance with embodiments of the present invention. FIG. 20 shows the arrangement of the integrated circuit in this embodiment from the bottom perspective. FIG. 21 shows the dies connected by the bottom structure from the side perspective. As shown in FIGS. 20 and 21, GaN transistor dies Die12-Die15 and silicon die Die16 can be disposed on the first surface of bottom structure 19. The second surface of bottom structure 19 (that is, the opposite surface of the first surface) may be provided with first pin 191, second pin 192, third pin 193, fourth pin 194, fifth pin 195, and a plurality of sixth pins 196.

For example, first pin 191 can connect to the first terminal of power switching device Q1 arranged in GaN transistor die Die12, second pin 192 can connect to the second terminal of power switching device Q4 provided in GaN transistor die Die15, third pin 193 can connect to a common node between power switching device Q1 arranged in GaN transistor die Die12 and power switching device Q2 provided on GaN transistor die Die13, fourth pin 194 can connect to a common node between power switching device Q2 provided on GaN transistor die Die13 and power switching device Q3 provided on GaN transistor die Die14, and fifth pin 195 can connect to a common node between power switching device Q3 provided on GaN transistor die Die14 and power switching device Q4 provided on GaN transistor die Die15. That is, first to fifth pins 191 to 195 may correspond to input voltage pin VIN, power stage ground terminal PGND, and pins SW1 to SW3 in FIG. 18, respectively. GaN transistor die Die12-Die15 can be sequentially arranged clockwise or counterclockwise in a matrix mode, such that adjacent power switching devices in the circuit structure can be easily interconnected through the bottom structure.

For example, GaN transistor dies Die12 and Die13 can be arranged adjacent to each other in the vertical direction (e.g., the first direction) in FIG. 20. GaN transistor dies Die13 and Die14 can be arranged adjacent to each other in the left-right direction (e.g., the second direction) in the FIG. 20. GaN transistor dies Die14 and Die15 may be arranged adjacent to each other along the first direction. GaN transistor dies Die12 and Die15 can be adjacently arranged along the second direction. Silicon die Die16 may be arranged on one side of the matrix formed by the GaN transistor dies. In this example, because third pin 193, fourth pin 194, and fifth pin 195 are all connected to the power switching devices in two GaN transistor dies, the projection of third pin 193 can cover the adjacent area of GaN transistor die Die12 and GaN transistor die Die13, the projection of fourth pin 194 can cover the adjacent area of GaN transistor Die13 and GaN transistor Die14, and the projection of fifth pin 195 can cover the adjacent area of GaN transistor Die14 and GaN transistor Die15, in order to shorten the length of the connecting lines. First pin 191 and second pin 192 can cover the edge area of the corresponding connected GaN transistor die. Therefore, the pins of each power stage can be connected with the connection terminals on the corresponding die in substantially the shortest distance, further reducing the negative influence of parasitic effect.

A plurality of sixth pins 196 can connect to control circuit 181. Because sixth pin 196 may connect to the control circuit, the current difference between the control stage and the power stage can be relatively large, so the areas of first to fifth pins 191-195 connected to power switching devices can be larger than the areas of each of sixth pins 196. In addition, each pin can be set as a rectangle and may cover as large an area as possible, in order to improve the conductive contact area. Also, the sizes and shapes of the first to sixth pins can be set according to the specific needs of integrated circuit design. As shown in FIG. 21, silicon die Die16 and GaN transistor dies Die12-Die15 can connect to the pins on the second surface of bottom structure 19 through metal structure 197 and vias formed in bottom structure 19, and can also connect to each other through internal metal structure 197 and vias.

FIG. 20 shows an exemplary arrangement way of GaN transistor dies Die7-Die10, but the arrangement of the GaN transistor dies and the silicon die on the bottom structure can be adjusted in certain embodiments. For example, the positions of GaN transistor die Die12 and GaN transistor die Die15 can be interchanged, and the positions of GaN transistor die Die13 and GaN transistor die Die14 interchanged. As another example, the GaN transistor dies may be distributed at the four corners of the bottom structure, the silicon die can be arranged in the middle of the first surface of the bottom structure, and the position and size of the pins may be adaptively adjusted.

In order to further improve the integration level, a plurality of power switching devices can also be integrated in one GaN transistor die; that is, two GaN transistor dies adopted, and each GaN transistor die may be provided with two power switching devices connected with each other. For example, all the power switching devices can be integrated in the same GaN transistor die, or all the power switching devices and the control circuit may be integrated together in the same GaN transistor die.

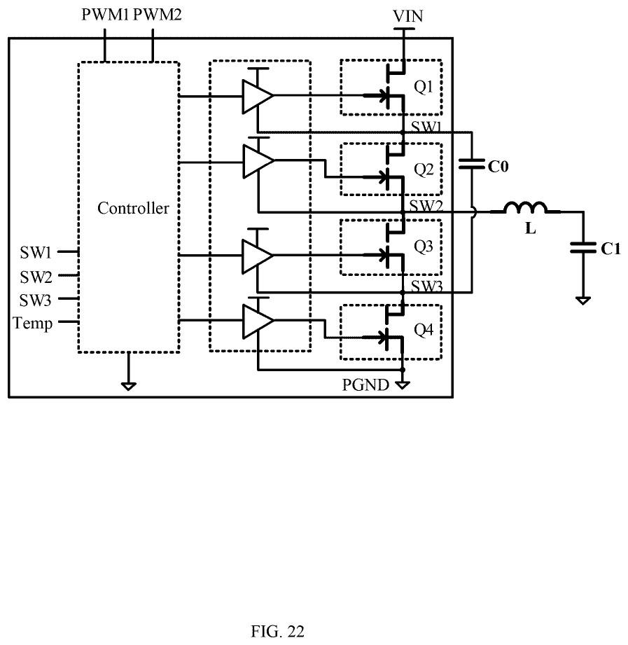

The integrated circuit of particular embodiments can cooperate with passive devices, such as external inductors and capacitors, in order to form a three-level buck power converter. Referring now to FIG. 22, shown is a schematic circuit diagram of a third example power converter, in accordance with embodiments of the present invention. In this particular example, flying capacitor C0 can connect between pins SW1 and SW3 of the integrated circuit, pin SW2 can connect to one terminal of inductor L1, and the other terminal of inductor L1 can connect to capacitor C1, thus forming a three-level buck power converter. By changing the connection relationship of power switching device in the integrated circuit, the integrated circuit can also be made suitable for building a power converter of other topological types (e.g., a three-level boost type power converter, etc.).

In particular embodiments, a GaN transistor die with a power switching device and a silicon die with a control circuit can be integrated on the same bottom structure, in order to form a driving integrated circuit with control functionality. In this way, parasitic effects between different power switching devices of the GaN transistor die can be effectively reduced, and chip performance improved due to the relatively short length of wires in the integrated circuit and relatively large contact surface of wires in the integrated circuit.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. An integrated circuit, comprising:
a) a bottom structure;
b) at least one GaN transistor die, wherein each GaN transistor die comprises at least one power switching device;
c) a silicon die comprising a control circuit for controlling the power switching device; and
d) wherein the GaN transistor die and the silicon die are arranged on the bottom structure, and an electrical connection between the control circuit and the power switching device comprises corresponding patterned metal structures arranged in the bottom structure.

2. The integrated circuit of claim 1, wherein:
a) the at least one GaN transistor die comprises a first GaN transistor die and a second GaN transistor die;
b) the first GaN transistor die comprises a first power switching device, the second GaN transistor die comprises a second power switching device; and
c) the first power switching device and the second power switching device are electrically connected to the control circuit of the silicon die through metal structures arranged in the bottom structure.

3. The integrated circuit of claim 2, wherein:
a) the first GaN transistor die and the second GaN transistor die are arranged on a first surface of the bottom structure;
b) a second surface of the bottom structure comprises a first pin coupled to a first terminal of the first power switching device, a third pin coupled to a second terminal of the second power switching device, and a second pin coupled to a common node between the first power switching device and the second power switching device; and
c) the second surface is opposite to the first surface.

4. The integrated circuit of claim 3, wherein the second surface of the bottom structure comprises a plurality of fourth pins electrically connected to the silicon die.

5. The integrated circuit of claim 4, wherein the first pin, the third pin, and the second pin are sequentially arranged along an arrangement direction of the first GaN transistor die and the second GaN transistor die, and wherein the fourth pins are arranged around the silicon die.

6. The integrated circuit of claim 1, wherein:
a) a number of GaN transistor dies is one;
b) the GaN transistor die comprises a first power switching device and a second power switching device;
c) a second terminal of the first power switching device is coupled to a first terminal of the second power switching device; and
d) the first power switching device and the second power switching device are electrically connected to the control circuit of the silicon die through metal structures arranged in the bottom structure.

7. The integrated circuit of claim 6, wherein:
a) the GaN transistor die and the silicon die are arranged on a first surface of the bottom structure;
b) a second surface of the bottom structure comprises a first pin coupled to a first terminal of the first power switching device, a third pin coupled to a second terminal of the second power switching device, and a second pin coupled to a common node between the first power switching device and the second power switching device; and
c) the second surface is opposite to the first surface.

8. The integrated circuit of claim 1, wherein:
a) the at least one GaN transistor die comprises a first GaN transistor die, a second GaN transistor die, a third GaN transistor die, and a fourth GaN transistor;
b) the first GaN transistor die comprises a first power switching device, the second GaN transistor die comprises a second power switching device, the third GaN transistor die comprises a third power switching device, the fourth GaN transistor die comprises a fourth power switching device; and
c) the first power switching device, the second power switching device, the third power switching device and the fourth power switching device are electrically connected to the control circuit of the silicon die through metal structures arranged in the bottom structure.

9. The integrated circuit of claim 8, wherein:
a) the first power switching device, the second power switching device, the third power switching device and the fourth power switching device are sequentially coupled in series through the bottom structure and are arranged on a first surface of the bottom structure;
b) a second surface of the bottom structure comprises a first pin coupled to a first terminal of the first power switching device, a second pin coupled to a second terminal of the fourth power switching device, a third pin coupled to a common node between the first and second power switching devices, a fourth pin coupled to a common node between the second and third power switching devices, and a fifth pin coupled to a common node between the third and fourth power switching devices; and
c) the second surface is opposite to the first surface.

10. The integrated circuit of claim 9, wherein:
a) the first GaN transistor die, the second GaN transistor die, the third GaN transistor die, and the fourth GaN transistor die are arranged in an array mode;
b) the first GaN transistor die and the second GaN transistor die are adjacently arranged along a first direction, the second GaN transistor die and the third GaN transistor die are adjacently arranged along a second direction, the third GaN transistor die and the fourth GaN transistor die are adjacently arranged along the first direction, and the first GaN transistor die and the fourth GaN transistor die are adjacently arranged along the second direction; and
c) the third pin covers an adjacent area of the first and second GaN transistor dies, the fourth pin covers an adjacent area of the second and third GaN transistor dies, and the fifth pin covers an adjacent area of the third and fourth GaN transistor dies.

11. The integrated circuit of claim 9, wherein the first GaN transistor die, the second GaN transistor die, the third GaN transistor die, and the fourth GaN transistor die are sequentially arranged in a clockwise or counterclockwise direction.

12. The integrated circuit of claim 8, wherein:
a) the first power switching device and the second power switching device are coupled in series through the bottom structure, the third power switching device and the fourth power switching device are coupled in series through the bottom structure, and the first GaN transistor die, the second GaN transistor die, the third GaN transistor die and the fourth GaN transistor die are arranged on a first surface of the bottom structure;
b) a second surface of the bottom structure comprises a first pin coupled to a first terminal of the first power switching device and a first terminal of the third power switching device, a second pin coupled to a second terminal of the second power switching device and a second terminal of the fourth power switching device, a third pin coupled to a common node between the first power switching device and the second power switching device, and a fourth pin coupled to a common node between the third power switching device and the fourth power switching device; and
c) the second surface is opposite to the first surface.

13. The integrated circuit of claim 12, wherein:
a) the silicon die is arranged in the middle of the first surface, the first and second GaN transistor dies are arranged on a first side of the silicon die, and the third and fourth GaN transistor dies are arranged on a second side of the silicon die; and
b) the first pin both covers part of the first GaN transistor die and part of the third GaN transistor die, the second pin is arranged in the middle of the second surface and spaced from the first pin, and the third pin and the fourth pin are arranged at the lower part of the second surface.

14. The integrated circuit of claim 12, wherein:
a) the silicon die is arranged in the middle of the first surface;
b) the first GaN transistor die, the second GaN transistor die, the third GaN transistor die and the fourth GaN transistor die are arranged at the periphery of the silicon die; and
c) the first GaN transistor die and the second GaN transistor die are adjacently arranged along a first direction, the second GaN transistor die and the fourth GaN transistor die are adjacently arranged along a second direction, the fourth GaN transistor die and the third GaN transistor die are adjacently arranged along the first direction, and the first GaN transistor die and the third GaN transistor die are adjacently arranged along the second direction.

15. The integrated circuit of claim 1, wherein:
a) the control circuit comprises a controller and a driving circuit, and the driving circuit comprises at least one buffer; and
b) the at least one buffer is correspondingly arranged according to the at least one power switching device, and each buffer is coupled between the controller and a control terminal of a corresponding power switching device.

16. An integrated circuit, comprising:
a) a bottom structure;
b) at least one GaN transistor die, wherein each GaN transistor die comprises a plurality of power switching devices and a control circuit electrically connected to the plurality of power switching devices; and
c) wherein the GaN transistor die is arrange on the bottom structure.

17. A power converter, comprising:
a) the integrated circuit of claim 1; and
b) at least one inductor coupled to the integrated circuit.
